(19) United States
(12) Patent Application Publication
(10) Pub. No.: US 2012/0000516 A1
(43) Pub. Date: Jan. 5, 2012

(54) Graphene Solar Cell

(75) Inventors: Ageeth A. Bol, Yorktown Heights, NY (US); Amal Kasry, White Plains, NY (US); Ahmed Maarouf, Mohegan Lake, NY (US); Glenn J. Martyna, Croton on Hudson, NY (US); Dennis M. Newns, Yorktown Heights, NY (US); Razvan A. Nistor, New York, NY (US); George S. Tulevski, Yorktown Heights, NY (US)

(73) Assignees: EGYPT NANOTECHNOLOGY CENTER, Cairo (EG); INTERNATIONAL BUSINESS MACHINES CORPORATION, Armonk, NY (US)

(21) Appl. No.: 12/828,446

(22) Filed: Jul. 1, 2010

(51) Int. Cl. H01L 31/0288; H01L 31/18; H01L 31/0256

(52) U.S. Cl. 136/255; 136/261; 438/98; 257/E31.11; 257/E31.002

(57) ABSTRACT

A solar cell includes a semiconductor portion, a graphene layer disposed on a first surface of the semiconductor portion, and a first conductive layer patterned on the graphene layer, the first conductive layer including at least one bus bar portion and a plurality of fingers extending from the at least one bus bar portion.

### CROSS REFERENCE TO RELATED APPLICATIONS

This application is related to co-pending application docket number YOR92010147US1, all of which is incorporated by reference herein.

### FIELD OF INVENTION

The present invention relates generally to semiconductor devices and, more particularly, to graphene solar cells.

### DESCRIPTION OF RELATED ART

Solar cells that are fabricated from amorphous silicon (a-Si) or other type of low conductivity semiconductor material often include a transparent conducting overlayer (TCO) that includes a film of Indium Tin Oxide (ITO) or Al-doped ZnO. The TCO should have relatively low resistivity and high transparency. Fabricating the film is often expensive, and the resultant films are undesirably brittle.

### BRIEF SUMMARY

In an exemplary embodiment, a solar cell includes a semiconductor portion, a graphene layer disposed on a first surface of the semiconductor portion, and a first conductive layer patterned on the graphene layer, the first conductive layer including at least one bus bar portion and a plurality of fingers extending from the at least one bus bar portion.

In another exemplary embodiment, a method for forming a solar cell includes forming a graphene layer on a metallic film, forming a polymethyl-methacrylate (PMMA) layer on the graphene layer, removing the metallic film from the graphene layer, disposing the graphene layer and the PMMA layer on a first surface of a semiconductor portion such that the graphene layer contacts the first surface of the semiconductor portion, removing the PMMA layer to expose the graphene layer, forming a first conductive layer on the exposed graphene layer, and removing a portion of the first conductive layer to pattern a bus bar and a plurality of fingers in the first conductive layer.

In still another exemplary embodiment, a method for forming a solar cell includes forming a copper film layer on a substrate material, forming a graphene layer on the copper film layer, disposing the graphene layer, the copper film layer, and the substrate material on a first surface of a semiconductor portion such that the graphene layer contacts the first surface of the semiconductor portion, removing the substrate material to expose copper film layer, and removing a portion of the copper film layer to pattern a bus bar and a plurality of fingers in the copper film layer.

### BRIEF DESCRIPTION OF THE SEVERAL VIEWS OF THE DRAWINGS

Referring to the exemplary drawings wherein like elements are numbered alike in the several Figures:

FIG. 1 illustrates a side cut-away view of an exemplary embodiment of a solar cell.

FIG. 2 illustrates a top view of a portion of the cell of FIG. 1.

FIGS. 3-6 illustrate an exemplary method for fabricating a solar cell.

FIGS. 7-9 illustrate an alternate exemplary method for fabricating a solar cell.

### DETAILED DESCRIPTION

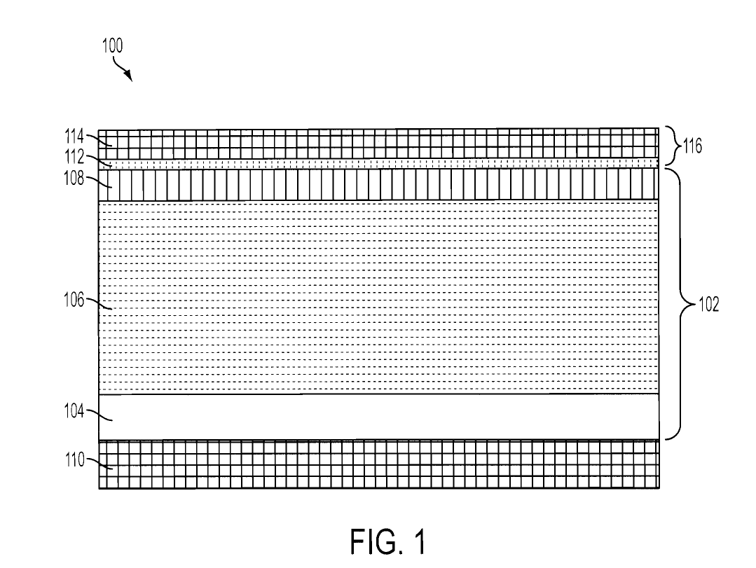

FIG. 1 illustrates a side cut-away view of an exemplary embodiment of a solar cell 100. The cell 100 includes a semiconductor portion 102 that may include, for example, amorphous silicon (a-Si) having an n-type doped region 104, an intrinsic semiconductor region 106, and a p-type doped region 108. A metallic layer 110 that may include, for example, copper, aluminum, or silver is disposed on the n-type doped region 104. A graphene layer (graphene monolayer) 112 is disposed on the p-type doped region 108. A conductive bus layer 114 is disposed on the graphene layer 112 and may be patterned from a conductive metal such as, for example, copper or silver. The graphene layer 112 and the conductive bus layer 114 form a transparent conducting overlayer (TCO) portion 116.

It is desirable to fabricate the cell 100 such that the transparency of the TCO layer 112 is greater than or equal to 85% with a resistance per square of less than 10 ohms. Though the graphene layer 112 satisfies the desired transparency parameters for the cell 100, the resistance of the graphene layer 112 without the conductive bus layer 114 is greater than desired. Fabricating the conductive bus layer 114 on the graphene layer 112 to form the TCO portion 116 reduces the resistivity of the TCO portion 116 to be within the desired resistance parameters while maintaining the desired transparency parameters. The use of graphene in the cell 100 may advantageously allow the cell 100 to be flexible such that the cell 100 may conform and be applied to curved surfaces.

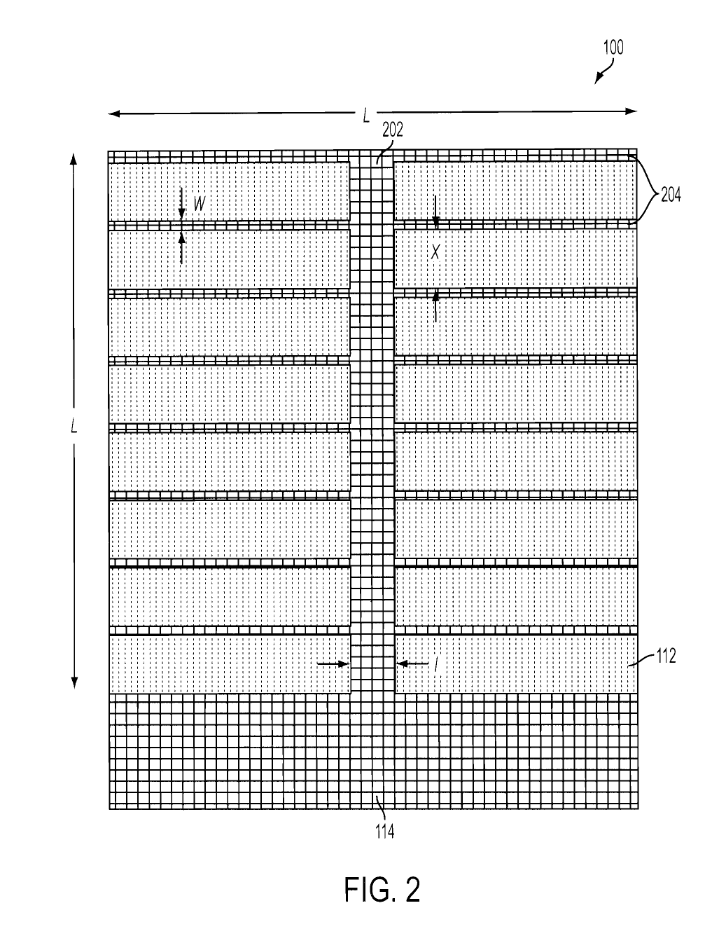

FIG. 2 illustrates a top view of a portion of the cell 100. The illustrated embodiment includes the conductive bus layer 114. The conductive bus layer 114 includes at least one bus portion 202 and a plurality of finger portions 204 (fingers).

In operation, the graphene layer 112 collects current from the underlying semiconductor portion 102. The conductive bus layer 114 pattern collects current from the graphene layer 112.

Referring to FIG. 2, to maintain transparency, the conductive bus layer 114 covers approximately 8% of the surface area of the solar cell 100. The conductive bus layer 114 has dimensions L×L, the bus portion 202 width is l, the finger 204 width is w, and the finger 204 spacing is x. Denoting by N the (number of fingers+1) on each side of a bus portion 202, N≈L/x. N=8 in the illustrated embodiment, but the number N may include any number of fingers 204. The thickness of the conductive bus layer 114 is t, and the resistivity of the metal ρ.

Assuming that the fingers 204 and the bus portion 202 (busbar) each take up 4% of the surface area, and the metal used to fabricate the conductive bus layer 114 is copper (Cu) results in:

$$\frac{NwL}{{L}^{2}} = \frac{w}{x} = 0.04 ,$$

for the fingers, and

$$\frac{Ll}{{L}^{2}} = \frac{l}{L} = 0.04 ,$$

for the busbar.

The resistance per square (R^{□}_{Cu}) of the Cu is

$${R}_{Cu}^{•} = \frac{ρ}{t} .$$

The resistance of a finger is:

$${R}_{f} = \frac{L}{2 w} {R}_{Cu}^{•} ,$$

And the total resistance due to all the fingers, as seen by the busbar 202 is

$${R}_{f}^{tot} = ( \frac{L}{2 w} ) ( \frac{1}{2 N} ) {R}_{Cu}^{•} = \frac{x}{4 w} {R}_{Cu}^{•} = \frac{25}{4} {R}_{Cu}^{•} .$$

The resistance of the busbar 202 is:

$${R}_{bb} = ( \frac{L}{l} ) {R}_{Cu}^{•} = 25 {R}_{Cu}^{•} .$$

Hence the total Cu resistance is:

$${R}_{Cu}^{tot} = ( 25 + \frac{25}{4} ) {R}_{Cu}^{•} = \frac{125}{4} {R}_{Cu}^{•} .$$

If Cu thickness t=1 um, and ρ=2×10⁻⁶ Ohm cm, the total Cu resistance is:

R_{Cu}^{tot}=0.6 Ohm.

The resistance per square is dominated by the graphene resistance R_{g}^{tot}. Estimated as:

$${R}_{Cu}^{tot} = \frac{1}{4 {N}^{2}} {R}_{g}^{•} = \frac{{x}^{2}}{4 {L}^{2}} {R}_{g}^{•} ,$$

Where R^{□}_{g} is the resistance per square of the graphene layer 112.

The Cu resistance can be ignored if the Cu thickness is approximately 1 um. The smallest in-plane dimension, the finger thickness w, is used to determine the overall pattern scale. If screen printing is used, the finger thickness may be as small as w=60 um. If w=60 um, and N=20, then:

x=0.15 cm,

L=3 cm,

l=0.12 cm.

The resistance per square is, (assuming dominance by the graphene resistance):

$${R}_{g}^{tot} \frac{1}{4 {( 20 )}^{2}} {R}_{g}^{•} = \frac{1}{1600} {R}_{g}^{•} .$$

Thus, the graphene resistance per square may be up to 16000 Ohm per square while maintaining 10 Ohm per square for the TCO portion 116. The transparency of the graphene monolayer 112 is >85% for a doped or undoped graphene layer 112 (the transparency value for undoped graphene is approximately 97%). The pattern of the conductive bus layer 114 obscures approximately 8% of the surface area of the graphene layer 112. Therefore, the desired combination of properties, transparency of >85% and sheet resistance <10 Ohm per square, is achieved with the combination of the graphene monolayer 116 and the conductive bus layer 114.

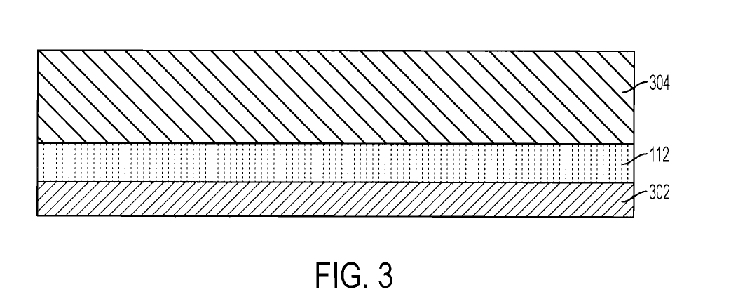

FIGS. 3-6 illustrate an exemplary method for fabricating the cell 100. Referring to FIG. 3, the graphene layer 112 is formed on a copper foil 302 with a chemical vapor deposition method (CVD) where the copper foil 302 is exposed to a carbon containing gas such as, for example, Ethylene at approximately 875° C. for approximately 30 minutes. A polymethyl-methacrylate (PMMA) layer 304 is spin coated on the graphene layer 112.

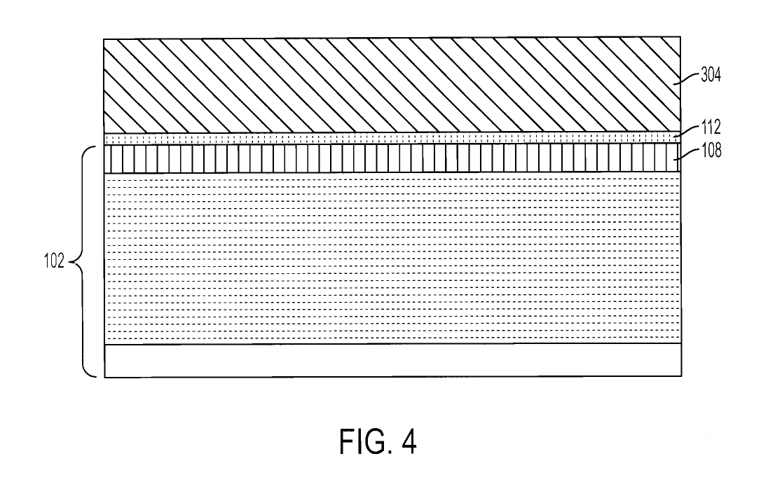

In FIG. 4, the graphene layer 112 is separated from the copper foil 302 by dissolving the copper in 1M solution of iron Chloride. The graphene layer 112 with the PMMA layer 304 is placed onto the p-type doped region 108 of the semiconductor portion 102 with the graphene in contact with the p-type doped region 108.

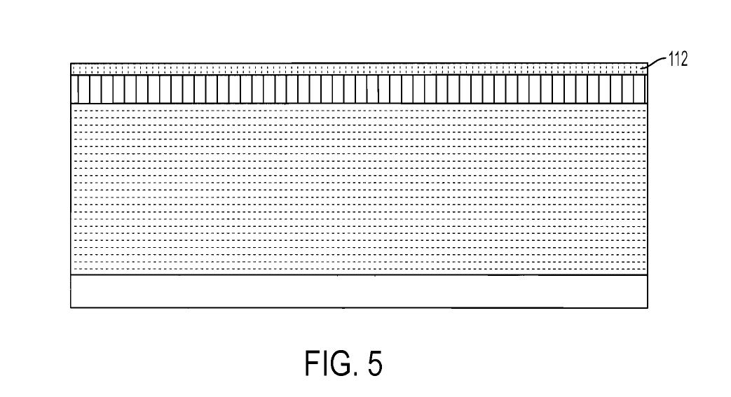

In FIG. 5, the PMMA layer 304 (of FIG. 4) is removed by, for example, dissolving the PMMA layer 304 in Acetone for approximately 1 hour at 80° C.

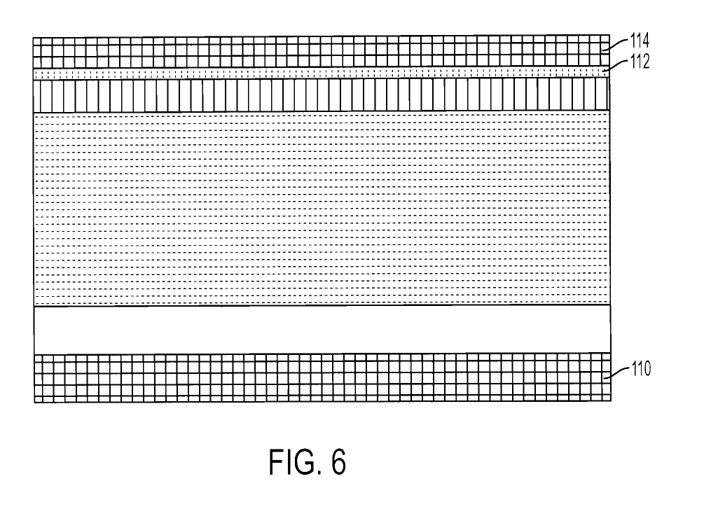

In FIG. 6, the conductive bus layer 114 is deposited on the graphene layer 112 by, for example, a lithographic masking and deposition process. The metallic layer 110 may be formed, for example, during the formation of the conductive bus layer 114, prior to the formation of the conductive bus layer 114, or following the formation of the conductive bus layer 114.

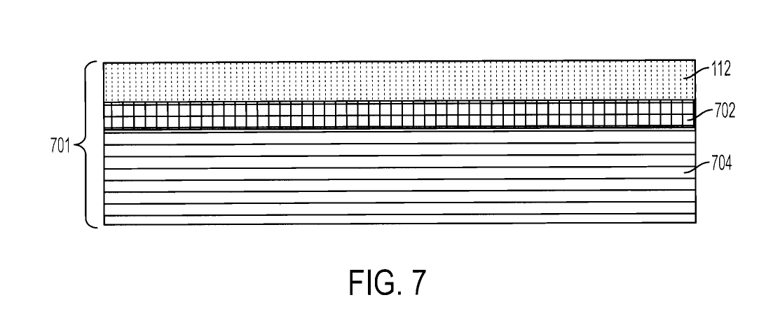

FIGS. 7-9 illustrate an alternate exemplary fabrication method for the cell 100. Referring to FIG. 7, a 200-1000 nm thick Cu film 702 is formed on a suitable thin-film substrate 704 such as, for example, Fe. The thin-film substrate is capable of supporting the 875° C. graphene reaction temperature, and to be separable from the Cu film 702 by, for example, dissolution in a suitable solvent, which does not dissolve Cu, such as hydrochloric or sulfuric acid in the case of Fe. A graphene layer 112 is formed on the Cu film 702 by, for example, a chemical vapor deposition method (CVD) where the Cu film 702 was exposed to a carbon containing gas Ethylene at approximately 875° C. for 30 minutes.

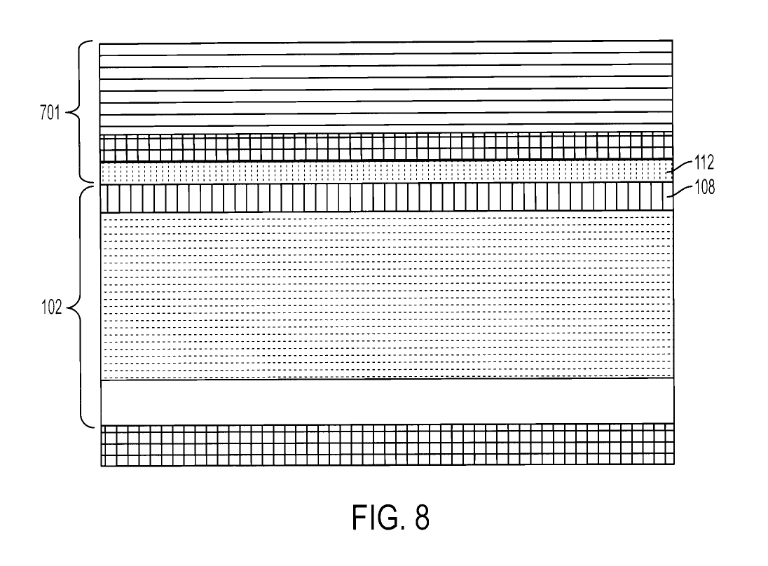

Referring to FIG. 8, the resultant Cu film 702, thin-film substrate 704, and graphene layer 112 structure 701 is placed onto the p-type doped region 108 of the semiconductor portion 102 with the graphene in contact with the p-type doped region 108.

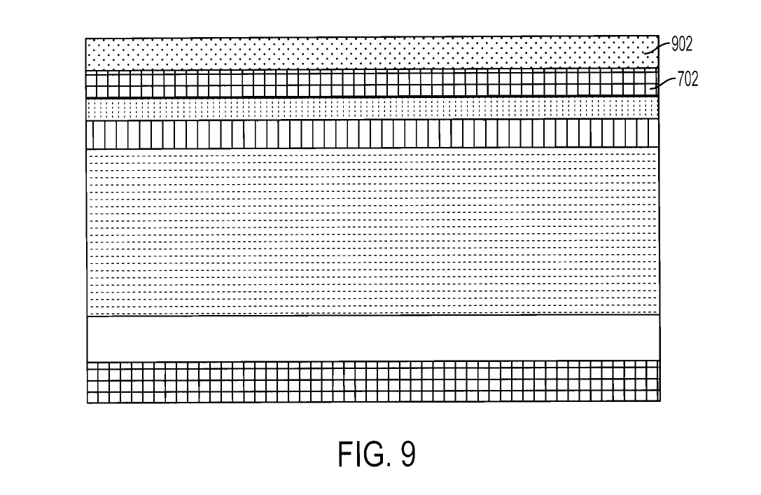

In FIG. 9, thin-film substrate 704 (of FIG. 8) is removed by, for example, dissolution in a suitable solvent, such as hydrochloric or sulfuric acid in the case of Fe. Using a process such as, for example, screen printing a resist stencil 902 (e.g. a lacquer-type resist stencil) for a desired pattern of a conductive bus layer is printed onto the Cu film 702. The Cu film 702 that not covered by the lacquer resist is removed by, for example etching with a reagent such as a 1M solution of iron Chloride leaving a resultant conductive bus layer similar to the conductive bus layer 114 of FIGS. 1 and 2 described above. The resist stencil 902 is dissolved by, for example an organic solvent. Electrodes for external contact are applied to the conductive bus layer 114 and the metallic layer 110 (of FIG. 1), and a transparent insulating protective layer (not shown) is deposited on the conductive bus layer 114.

While the invention has been described with reference to a preferred embodiment or embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

What is claimed is:

1. A solar cell comprising:
a semiconductor portion;
a graphene layer disposed on a first surface of the semiconductor portion; and
a first conductive layer patterned on the graphene layer, the first conductive layer including at least one bus bar portion and a plurality of fingers extending from the at least one bus bar portion.

2. The cell of claim 1, wherein the first surface of the semiconductor portion includes a p-type doped region.

3. The cell of claim 1, wherein the semiconductor portion includes a second surface having an n-type doped region.

4. The cell of claim 3, wherein the cell includes a second conductive layer disposed on the second surface of the semiconductor portion.

5. The cell of claim 1, wherein the fingers and bus bar portion are operative to collect current from the graphene layer.

6. The cell of claim 1, wherein the cell first conductive layer includes copper.

7. The cell of claim 1, wherein the semiconductor portion includes amorphous silicon.

8. A method for forming a solar cell, the method including:
forming a graphene layer on a metallic film;
forming a polymethyl-methacrylate (PMMA) layer on the graphene layer;
removing the metallic film from the graphene layer;
disposing the graphene layer and the PMMA layer on a first surface of a semiconductor portion such that the graphene layer contacts the first surface of the semiconductor portion;
removing the PMMA layer to expose the graphene layer;
forming a first conductive layer on the exposed graphene layer; and
removing a portion of the first conductive layer to pattern a bus bar and a plurality of fingers in the first conductive layer.

9. The method of claim 8, wherein the method further includes forming a p-typed doped region on the first surface of the semiconductor portion prior to disposing the graphene layer and the PMMA layer on the first surface of the semiconductor portion.

10. The method of claim 8, wherein the method further includes forming an n-type doped region on a second surface of the semiconductor portion.

11. The method of claim 10, wherein the method further includes forming a second conductive layer on the second surface of the semiconductor portion.

12. The method of claim 8, wherein the first conductive layer includes copper.

13. A method for forming a solar cell, the method including:
forming a copper film layer on a substrate material;
forming a graphene layer on the copper film layer;
disposing the graphene layer, the copper film layer, and the substrate material on a first surface of a semiconductor portion such that the graphene layer contacts the first surface of the semiconductor portion;
removing the substrate material to expose copper film layer; and
removing a portion of the copper film layer to pattern a bus bar and a plurality of fingers in the copper film layer.

14. The method of claim 14, wherein the method further includes forming a p-typed doped region on the first surface of the semiconductor portion prior to disposing the graphene layer, the copper film layer, and the substrate material on the first surface of the semiconductor portion.

15. The method of claim 13, wherein the method further includes forming an n-type doped region on a second surface of the semiconductor portion.

16. The method of claim 16, wherein the method further includes forming a second conductive layer on the second surface of the semiconductor portion.

17. The method of claim 13, wherein the substrate material includes iron.

18. The method of claim 13, wherein the substrate material is removed using a solvent.

19. The method of claim 13, wherein the method includes lithographically patterning a lacquer based photoresist layer on the copper film layer prior to removing the portion of the copper film layer to pattern the bus bar and the plurality of fingers in the copper film layer.
